(19) United States
(12) Patent Application Publication
(10) Pub. No.: US 2026/0221348 A1
(43) Pub. Date: Jul. 30, 2026

(54) CAPACITOR, ELECTRIC CIRCUIT, CIRCUIT BOARD, AND APPARATUS

(71) Applicant: Panasonic Intellectual Property Management Co., Ltd., Osaka (JP)

(72) Inventors: Naoya KITAMURA, Osaka (JP); Hiroshi ASANO, Osaka (JP); Hisanori MASHIKO, Osaka (JP); Ryosuke KIKUCHI, Osaka (JP); Manabu KANOU, Osaka (JP); Hiromi MORITA, Osaka (JP)

(21) Appl. No.: 19/629,655

(22) Filed: Mar. 26, 2026

Related U.S. Application Data
(63) Continuation of application No. PCT/JP2025/014832, filed on Apr. 15, 2025.

(30) Foreign Application Priority Data
Jul. 18, 2024 (JP) 2024-114540

(51) Int. Cl. H01G 9/048; H01G 9/04; H01G 9/042; H01G 9/07; H01G 9/15; H01G 9/28; H05K 1/181

(52) U.S. Cl. CPC H01G 9/048; H01G 9/042; H01G 9/07; H01G 9/15; H01G 9/28; H05K 1/181; H01G 2009/05; H05K 2201/10015

(57) ABSTRACT

A capacitor includes a metallic tantalum, an electrical conductor, and a tantalum oxide film. The tantalum oxide film is disposed in contact with the metallic tantalum and between the metallic tantalum and the electrical conductor. The tantalum oxide film includes a first portion and a second portion. The first portion contains fluorine. The second portion is located closer to the metallic tantalum than the first portion in a thickness direction of the tantalum oxide film. In the tantalum oxide film, a fluorine concentration in the second portion is lower than a fluorine concentration in the first portion. A ratio d₁/d₀ of a thickness d₁ of the first portion to a thickness d₀ of the tantalum oxide film is more than 0.4 and 0.8 or less.

This application is a continuation of PCT/JP2025/014832 filed on Apr. 15, 2025, which claims foreign priority of Japanese Patent Application No. 2024-114540 filed on Jul. 18, 2024, the entire contents of both of which are incorporated herein by reference.

### BACKGROUND OF THE INVENTION

### 1. Field of the Invention

The present invention relates to a capacitor, an electrical circuit, a circuit board, and an apparatus.

### 2. Description of Related Art

It has been known that a fluorine-containing tantalum oxide is included in capacitors.

For example, in Journal of Materials Chemistry C, (UK), 2020, Issue 14, pp. 4680-4684, a thin polycrystalline TaO₂F film having a relative permittivity of 60 at 1 MHz is described.

JP 2005-294402 A describes a solid electrolytic capacitor including a dielectric layer formed of a tantalum oxide containing fluorine. The dielectric layer is formed by anodic oxidation of an anode formed of tantalum in an aqueous solution containing fluorine ions.

JP 7122617 B1 describes a capacitor including a dielectric including an amorphous tantalum compound containing fluorine and oxygen.

### SUMMARY OF THE INVENTION

The present disclosure provides a capacitor including a fluorine-containing tantalum oxide, the capacitor being advantageous in terms of the capacitance of the capacitor and the dielectric loss tangent of a tantalum oxide film.

A capacitor of the present disclosure includes:
metallic tantalum;
an electrical conductor; and
a tantalum oxide film disposed in contact with the metallic tantalum and between the metallic tantalum and the electrical conductor, wherein
the tantalum oxide film includes a first portion containing fluorine and a second portion located closer to the metallic tantalum than the first portion in a thickness direction of the tantalum oxide film,
a fluorine concentration in the second portion is lower than a fluorine concentration in the first portion, and
a ratio of a thickness of the first portion to a thickness of the tantalum oxide film is more than 0.4 and 0.8 or less.

The present disclosure can provide a capacitor including a fluorine-containing tantalum oxide, the capacitor being advantageous in terms of the capacitance of the capacitor and the dielectric loss tangent of a tantalum oxide film.

### BRIEF DESCRIPTION OF THE DRAWINGS

FIG. 1 is a cross-sectional view showing an example of the capacitor of the present disclosure.

FIG. 2 is a cross-sectional view showing another example of the capacitor of the present disclosure.

FIG. 3A schematically shows an example of the electrical circuit of the present disclosure.

FIG. 3B schematically shows an example of the circuit board of the present disclosure.

FIG. 3C schematically shows an example of the apparatus of the present disclosure.

FIG. 4 is a graph showing the results of X-ray diffraction (XRD) measurement of a sample according to Example 1B and metallic tantalum.

FIG. 5A is a graph showing a relationship between signal intensities of F⁻, TaO₃⁻, and O⁻ and the depth of a tantalum oxide film in a depth profile obtained from a sample according to Example 1A by time-of-flight secondary ion mass spectrometry (TOF-SIMS).

FIG. 5B is a graph showing a relationship between signal intensities of F⁻, TaO₃⁻, and O⁻ and the depth of a tantalum oxide film in a depth profile obtained from the sample according to Example 1B by TOF-SIMS.

FIG. 6A is a graph showing a relationship between signal intensities of F⁻, TaO₃⁻, and O⁻ and the depth of a tantalum oxide film in a depth profile obtained from a sample according to Comparative Example 1 by TOF-SIMS.

FIG. 6B is a graph showing a relationship between signal intensities of F⁻, TaO₃⁻, and O⁻ and the depth of a tantalum oxide film in a depth profile obtained from a sample according to Comparative Example 2 by TOF-SIMS.

FIG. 7A is a graph showing a relationship between a capacitance increase rate and a ratio of a thickness of a first portion to a thickness of a tantalum oxide film for samples according to Example 2A, Example 2B, Comparative Example 3, Comparative Example 4, and Comparative Example 5.

FIG. 7B is a graph showing a relationship between a dielectric loss tangent tan δ of the tantalum oxide film and the ratio of the thickness of the first portion to the thickness of the tantalum oxide film for the samples according to Example 2A, Example 2B, Comparative Example 3, Comparative Example 4, and Comparative Example 5.

### DETAILED DESCRIPTION

### Findings on which the Present Disclosure is Based

For example, there is a continuous demand for improving processing performance of electronic apparatuses. Performance of an electronic component, such as a capacitor, greatly affects performance of an electronic apparatus in which the component is embedded. Therefore, it is expected that there will be an increasing need for small high-performance capacitors. Electrolytic capacitors, for example, are known as capacitors. In an electrolytic capacitor, a dielectric formed of a thin oxidized film is provided on a surface of metallic aluminum or metallic tantalum by chemical conversion of aluminum or tantalum. For electrolytic capacitors, attempts have been made to increase the capacitance of a capacitor mainly by increasing the specific surface area of a dielectric. However, such attempts have limitations. It is thought that the capacitor performance will be able to be improved further by developing dielectric materials having higher permittivities.

For example, a thin polycrystalline TaO₂F film described in Journal of Materials Chemistry C, (UK), 2020, Issue 14, pp. 4680-4684 has a high relative permittivity. It is considered that a polycrystal of an oxyfluoride of tantalum has a crystal state different from that of tantalum oxide Ta₂O₅ and hence has a larger polarization and a higher relative permittivity. As described in JP 7122617 B1, a fluorine-containing tantalum oxide can have a higher relative permittivity than that of a fluorine-free tantalum oxide Ta₂O₅ even when the fluorine-containing tantalum oxide is amorphous. As just described, a capacitor including a fluorine-containing tantalum oxide is expected to have a higher capacitance.

According to JP 2005-294402 A, a dielectric layer is formed by anodic oxidation of an anode formed of tantalum in an aqueous solution containing fluorine ions. According to JP 2005-294402 A, an equivalent series resistance (ESR) of an electrolytic capacitor is small because the dielectric layer is formed of a tantalum oxide containing fluorine. However, according to the studies by the present inventors, a film obtained by anodic oxidation of tantalum in an aqueous solution containing fluorine ions can have a high dielectric loss tangent.

In view of such circumstances, the present inventors conducted intensive studies to determine whether it is possible to achieve both an increase in the capacitance of a capacitor and maintenance of a low dielectric loss tangent of a tantalum oxide while using a fluorine-containing tantalum oxide as a dielectric. As a result, the present inventors have newly found that, from the viewpoint of achieving both, it is important that a ratio of a thickness of a fluorine-containing portion of a tantalum oxide to a thickness of the tantalum oxide be in a certain range. On the basis of this new finding, the present inventors have completed the capacitor of the present disclosure.

### EMBODIMENTS

Embodiments of the present disclosure will be described hereinafter with reference to the drawings. The present disclosure is not limited to the following embodiments.

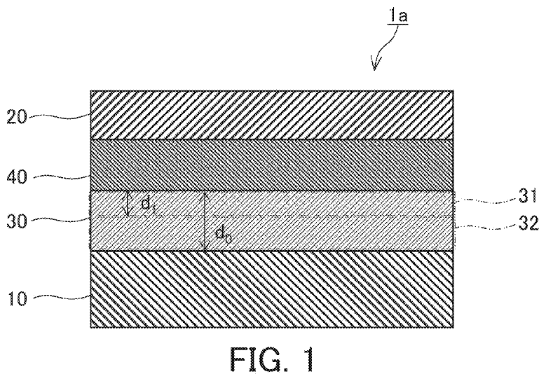

FIG. 1 is a cross-sectional view showing an example of the capacitor of the present disclosure. As shown in FIG. 1, a capacitor 1a includes metallic tantalum 10, an electrical conductor 20, and a tantalum oxide film 30. The tantalum oxide film 30 is disposed in contact with the metallic tantalum 10 and between the metallic tantalum 10 and the electrical conductor 20. The tantalum oxide film 30 includes a first portion 31 and a second portion 32. The first portion 31 contains fluorine. The second portion 32 is located closer to the metallic tantalum 10 than the first portion 31 in a thickness direction of the tantalum oxide film 30. The second portion 32 is, for example, in contact with the metallic tantalum 10. In the tantalum oxide film 30, a fluorine concentration in the second portion 32 is lower than a fluorine concentration in the first portion 31. A ratio d₁/d₀ of a thickness d₁ of the first portion to a thickness d₀ of the tantalum oxide film 30 is more than 0.4 and 0.8 or less. In this case, the capacitance of the capacitor 1a is likely to be high and the dielectric loss tangent of the tantalum oxide film 30 is less likely to be high. Therefore, the capacitor 1a is likely to exhibit desired performance.

Since the ratio d₁/d₀ is more than 0.4, the material of the tantalum oxide film 30 is likely to have a high relative permittivity and the capacitance of the capacitor 1a is likely to be high. In terms of enhancing the capacitance of the capacitor 1a, the ratio d₁/d₀ is desirably 0.42 or more, more desirably 0.45 or more, even more desirably 0.5 or more.

Since the ratio d₁/d₀ is 0.8 or less, the dielectric loss tangent of the tantalum oxide film 30 is less likely to be high. The ratio d₁/d₀ may be 0.80 or less, 0.7 or less, or 0.6 or less.

As shown in FIG. 1, the first portion 31 and the second portion 32 are each, for example, in a layer form.

The thickness of the first portion 31 of the tantalum oxide film 30 may be determined, for example, according to a depth profile obtained by TOF-SIMS. For example, in a depth profile obtained by TOF-SIMS, the maximum of the signal intensity of fluoride ion (F⁻) is identified within a range in which a fluoride ion (F⁻) signal can be accurately analyzed. The target range for identifying the maximum value is limited because, in analysis by TOF-SIMS or the like, the signal intensity may vary in an initial stage of the analysis due to an influence of surface deposits or the like. The maximum of the signal intensity of fluoride ion (F⁻) is identified within the above target range, and the thickness d₁ corresponding to a range in which the signal intensity is equal to or greater than one half of the maximum is determined as the thickness of the first portion 31. Note that the method for determining the thickness of the first portion 31 is not limited to the above method involving TOF-SIMS, and the thickness of the first portion 31 may be determined in the same manner, for example, using a depth profile obtained by RBS, TEM-EDX, or the like.

The thickness of the tantalum oxide film 30 of the capacitor 1a may be determined, for example, according to a depth profile obtained by TOF-SIMS. For example, in a depth profile, the maximum of the signal intensity of tantalum oxide ion (TaO³⁻) is identified within a range in which a tantalum oxide ion (TaO³⁻) signal can be accurately analyzed. The reason for limiting the target range in identifying the maximum value is as described above. The maximum of the signal intensity of tantalum oxide ion (TaO³⁻) is identified within the above target range, and the thickness d₀ corresponding to a range in which the signal intensity is equal to or greater than one half of the maximum is determined as the thickness of the tantalum oxide film 30. Note that the method for determining the thickness of the tantalum oxide film 30 is not limited to the above method involving TOF-SIMS, and the thickness of the tantalum oxide film 30 may be determined in the same manner, for example, using a depth profile obtained by RBS, TEM-EDX, or the like.

TOF-SIMS as described above may be performed at any one location selected in an in-plane direction of the tantalum oxide film 30, whereby the thickness d₁ of the first portion 31 and the thickness d₀ of the tantalum oxide film 30 can be determined, and a thickness d₂ of the second portion 32 can also be determined as a value (d₀-d₁) obtained by subtracting the thickness d₁ from the thickness d₀.

The dielectric loss tangent of the tantalum oxide film 30 is, for example, 0.12 or less at 120 Hz.

A capacitance increase rate of the capacitor 1a is, for example, 5% or more. The capacitance increase rate is expressed as a percentage of (C₁ₐ−C₀)/C₀, where C₁ₐ is a capacitance of the capacitor 1a and C₀ is a capacitance of a capacitor according to a reference example. The capacitor according to the reference example is a capacitor including a fluorine-free tantalum oxide film instead of the tantalum oxide film 30. The capacitance C₁ₐ and the capacitance C₀ may be determined, for example, by a method described in EXAMPLES.

The thickness of the tantalum oxide film 30 is not limited to a particular thickness. The tantalum oxide film 30 has a thickness of, for example, 1 μm or less. In this case, the tantalum oxide film 30 is able to be formed by anodic oxidation. The tantalum oxide film 30 is, for example, an anodic film. The tantalum oxide film 30 has a thickness of, for example, 1 nm or more.

The first portion 31 may be crystalline or amorphous. Even when the first portion 31 is amorphous, the tantalum oxide film 30 is likely to have a high relative permittivity, and the capacitor 1a is likely to have a high capacitance. For example, an object can be concluded to be amorphous when a broad halo pattern appears in an XRD pattern obtained from the object using Cu-Kα radiation at diffraction angles 2θ from 10° to 50°.

The second portion 32 may be crystalline or amorphous.

A composition of the first portion 31 is not limited to a particular composition as long as the fluorine concentration in the second portion 32 is lower than the fluorine concentration in the first portion 31. The first portion 31 is, for example, free of silicon and titanium. The first portion 31 has a composition, for example, represented by TaOₓ₁F_{y1}. This composition satisfies, for example, requirements 0<x1<2.5 and 0<y1≤0.40. In this case, the tantalum oxide film 30 is more likely to have a high relative permittivity, and the capacitor 1a is more likely to have a high capacitance. Moreover, in this case, the fluorine included in the tantalum oxide film 30 is unlikely to diffuse toward the metallic tantalum 10 under influence of an electric field, heat, or the like, and the dielectric loss tangent of the tantalum oxide film 30 is less likely to be high.

The composition of the second portion 32 is not limited to a particular composition as long as the fluorine concentration in the second portion 32 is lower than the fluorine concentration in the first portion 31. The second portion 32 is, for example, free of silicon and titanium. The second portion 32 has a composition, for example, represented by TaOₓ₂F_{y2}. This composition satisfies, for example, requirements 0<x2<2.5 and 0<y2≤0.015. In this case, a fluorine concentration in the tantalum oxide film 30 is much less likely to be high in a vicinity of the metallic tantalum 10, and the dielectric loss tangent of the tantalum oxide film 30 is much less likely to be high.

The values of x1, x2, y1, and y2 in the above compositions can be determined, for example, according to results of Rutherford backscattering spectrometry (RBS). The values of x1, x2, y1, and y2 may be determined by a combination of TOF-SIMS and another analysis method, such as Rutherford backscattering spectrometry (RBS).

As shown in FIG. 1, the capacitor 1a includes, for example, an electrolyte 40. The electrolyte 40 is disposed between the tantalum oxide film 30 and the electrical conductor 20 in the thickness direction of the tantalum oxide film 30. In this case, the capacitor 1a is provided, for example, as an electrolytic capacitor. In the capacitor 1a, the electrolyte 40 forms, for example, a layer. The electrolyte 40 may be omitted in the capacitor 1a.

The electrolyte 40 is not limited to a particular electrolyte. The electrolyte 40 includes, for example, at least one selected from the group consisting of an electrolyte solution and an electrically conductive polymer. Examples of the electrically conductive polymer include polypyrrole, a polythiophene, polyaniline, and derivatives of these. The electrolyte 40 may be a manganese compound, such as manganese oxide. The electrolyte 40 may include a solid electrolyte.

In the capacitor 1a, the material of the electrical conductor 20 is not limited to a particular material. The electrical conductor 20 may include a valve metal, such as aluminum, tantalum, niobium, or bismuth, may include a noble metal, such as gold or platinum, or may include nickel. The electrical conductor 20 may include a carbon material, such as graphite.

The method for forming the tantalum oxide film 30 is not limited to a particular method. The tantalum oxide film 30 is formed, for example, by a method including (I) and (II) below.
(I) Performing anodization of metallic tantalum with the metallic tantalum in contact with a fluorine-free aqueous solution to form an oxide layer in contact with the metallic tantalum.
(II) Performing anodization of the metallic tantalum with the oxide layer formed in (I) in contact with a fluorine-containing aqueous solution to give the tantalum oxide film 30 including the first portion 31 containing fluorine and the second portion 32.

During the anodization, for example, a voltage within the range of several volts [V] to several hundred volts [V] is applied between an anode and a cathode with an electrolyte disposed therebetween. For example, a voltage of 5 volts [V] to 300 volts [V] is applied. When the metallic tantalum is an anode, an anion attracted to the metallic tantalum and ionized tantalum are bonded to form a conversion coating. In this process, ions or atoms being electrolyte-derived impurities around the anode can be incorporated into the conversion coating. Therefore, it is practically impossible to form a film consisting only of two specific elements, such as tantalum and oxygen, in the anodization in which the metallic tantalum is used as an anode. Hence, for example, the second portion 32 can include an element, such as fluorine, other than tantalum and oxygen at a concentration of 0.4% or less on the basis of the number of atoms.

The ratio d₁/d₀ can be adjusted, for example, by the magnitude of the voltage applied between the anode and the cathode and the temperature of the electrolyte in the anodization. For example, when the voltage applied between the anode and the cathode in the anodization in (II) is constant, the ratio d₁/d₀ tends to decrease as the voltage applied between the anode and the cathode in the anodization in (I) increases. Additionally, the thickness of the tantalum oxide film 30 tends to increase as the temperature of the electrolyte in the anodization increases.

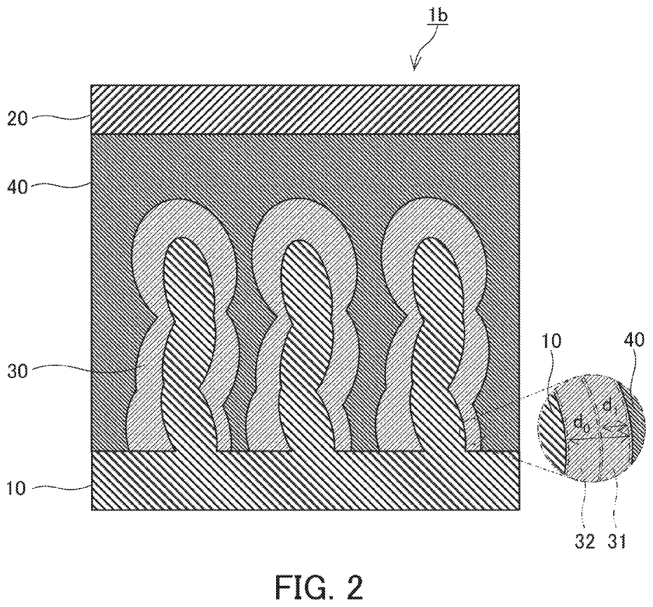

FIG. 2 is a cross-sectional view showing another example of the capacitor of the present disclosure. A capacitor 1b shown in FIG. 2 is configured in the same manner as the capacitor 1a unless otherwise described. The components of the capacitor 1b that are the same as or correspond to the components of the capacitor 1a are denoted by the same reference characters, and detailed descriptions of such components are omitted. The description given for the capacitor 1a is applicable to the capacitor 1b unless there is a technical inconsistency.

As shown in FIG. 2, at least a portion of the metallic tantalum 10 of the capacitor 1b is porous. This makes it likely that the metallic tantalum 10 has a large surface area and the capacitor 1b has a high capacitance. The porous structure can be formed, for example, by etching of a metallic foil, sintering of powder, or the like.

As shown in FIG. 2, the tantalum oxide film 30 is disposed on the porous portion of the metallic tantalum 10. The tantalum oxide film 30 is formed, for example, by anodization. The electrolyte 40 is disposed so as to fill a space around the porous portion of the tantalum oxide film 30. The electrolyte 40 includes, for example, at least one selected from the group consisting of a manganese oxide, an electrolyte solution, and an electrically conductive polymer. Examples of the electrically conductive polymer include polypyrrole, a polythiophene, polyaniline, and derivatives of these. The electrolyte 40 may be a manganese compound, such as manganese oxide. The electrolyte 40 may include a solid electrolyte. In the capacitor 1b, for example, a cathode is formed of the electrical conductor 20 and the electrolyte 40. The electrical conductor 20 may include, for example, a solidified body of a silver-including paste, a carbon material such as graphite, or both the solidified body and the carbon material.

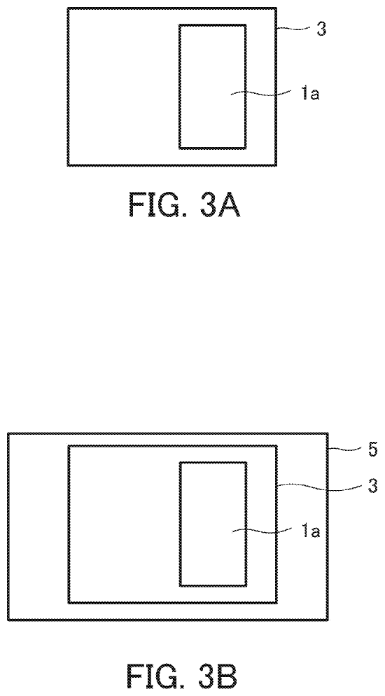

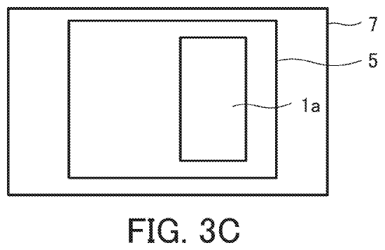

FIG. 3A schematically shows an example of the electrical circuit of the present disclosure. An electrical circuit 3 includes the capacitor 1a. The electrical circuit 3 may be an active circuit or a passive circuit. The electrical circuit 3 may be a discharging circuit, a smoothing circuit, a decoupling circuit, or a coupling circuit. Since the electrical circuit 3 includes the capacitor 1a, the electrical circuit 3 is likely to exhibit desired performance. For example, noise is likely to be reduced in the electrical circuit 3. The electrical circuit 3 may include the capacitor 1b.

FIG. 3B schematically shows an example of the circuit board of the present disclosure. As shown in FIG. 3B, a circuit board 5 includes the capacitor 1a. For example, the circuit board 5 includes the electrical circuit 3 including the capacitor 1a. Since the circuit board 5 includes the capacitor 1a, the circuit board 5 is likely to exhibit desired performance. The circuit board 5 may be an embedded board or a motherboard. The circuit board 5 may include the capacitor 1b.

FIG. 3C schematically shows an example of the apparatus of the present disclosure. As shown in FIG. 3C, an apparatus 7 includes the capacitor 1a. The apparatus 7 includes, for example, the circuit board 5 including the capacitor 1a. Since the apparatus 7 includes the capacitor 1a, the apparatus 7 is likely to exhibit desired performance. The apparatus 7 may be an electronic device, a communication device, a signal-processing device, or a power-supply device. The apparatus 7 may be a server, an AC adapter, an accelerator, or a flat-panel display such as a liquid crystal display (LCD). The apparatus 7 may be a USB charger, a solid-state drive (SSD), an information terminal such as a PC, a smartphone, or a tablet PC, or an Ethernet switch. The apparatus 7 may include the capacitor 1b.

### (Supplement)

According to the above description, the following techniques are disclosed.

### (Technique 1)

A capacitor including:
metallic tantalum;
an electrical conductor; and
a tantalum oxide film disposed in contact with the metallic tantalum and between the metallic tantalum and the electrical conductor, wherein
the tantalum oxide film includes a first portion containing fluorine and a second portion located closer to the metallic tantalum than the first portion in a thickness direction of the tantalum oxide film,
a fluorine concentration in the second portion is lower than a fluorine concentration in the first portion, and
a ratio of a thickness of the first portion to a thickness of the tantalum oxide film is more than 0.4 and 0.8 or less.

### (Technique 2)

The capacitor according to Technique 1, wherein the first portion is amorphous.

### (Technique 3)

The capacitor according to Technique 1 or 2, wherein
the first portion has a composition represented by TaOₓ₁F_{y1}, and
the composition satisfies requirements 0<x1<2.5 and 0<y1≤0.4.

### (Technique 4)

The capacitor according to any one of Techniques 1 to 3, wherein
the second portion has a composition represented by TaOₓ₂F_{y2}, and
the composition satisfies requirements 0<x2<2.5 and 0<y2≤0.015.

### (Technique 5)

The capacitor according to any one of Techniques 1 to 4, further including an electrolyte disposed between the tantalum oxide film and the electrical conductor in the thickness direction of the tantalum oxide film.

### (Technique 6)

An electrical circuit including the capacitor according to any one of Techniques 1 to 5.

### (Technique 7)

A circuit board including the capacitor according to any one of Techniques 1 to 5.

### (Technique 8)

An apparatus including the capacitor according to any one of Techniques 1 to 5.

### EXAMPLES

Hereinafter, the present disclosure will be described in more detail with reference to examples. The examples given below are just examples, and the present disclosure is not limited to them.

### Example 1A and Example 1B

Ultrasonic cleaning was performed for 10 minutes with a flat plate of metallic tantalum immersed in an acetone-filled container, thereby washing the surface of the metallic tantalum. After that, acetone on the surface of the metallic tantalum was evaporated, and the surface of the metallic tantalum was washed with pure water. The metallic tantalum was then dried in air. An anode foil was obtained in this manner.

The above anode foil and a platinum foil as a counter electrode were disposed such that they were partially immersed in an aqueous phosphoric acid solution with a given distance therebetween. The portion of the anode foil above the surface of the aqueous phosphoric acid solution was connected to a positive electrode of a power-supply device, while the portion of the platinum foil above the surface of the aqueous phosphoric acid solution was connected to a negative electrode of the power-supply device. In Example 1A and Example 1B, respectively, voltages of 50 V and 40 V were applied between the anode foil and the platinum foil for a given period of time, thereby forming a Ta₂O₅-including oxide layer on the surface of the anode foil. The anode foil was taken out of the aqueous phosphoric acid solution, washed with pure water, and then dried in air.

Next, the above anode foil with the oxide layer and a platinum foil as a counter electrode were disposed such that they were partially immersed in an aqueous mixture solution of NaF and a sodium phosphate buffer with a given distance therebetween. The portion of the anode foil above the surface of the aqueous mixture solution was connected to a positive electrode of a power-supply device, while the portion of the platinum foil above the surface of the aqueous mixture solution was connected to a negative electrode of the power-supply device. A voltage of 90 V was applied between the anode foil and the platinum foil for a given period of time to form a fluorine-containing tantalum oxide layer. Samples according to Example 1A and Example 1B in which a tantalum oxide film is provided on the surface of metallic tantalum were obtained in this manner.

### Comparative Example 1

A sample according to Comparative Example 1 was obtained in the same manner as in Example 1A and Example 1B, except that the voltage applied between the anode foil and the platinum foil was changed to 30 V in the oxide layer formation using the aqueous phosphoric acid solution.

### Comparative Example 2

A sample according to Comparative Example 2 was obtained in the same manner as in Example 1A and Example 1B, except that the voltage applied between the anode foil and the platinum foil was changed to 60 V in the oxide layer formation using the aqueous phosphoric acid solution.

### (X-Ray Diffraction Measurement)

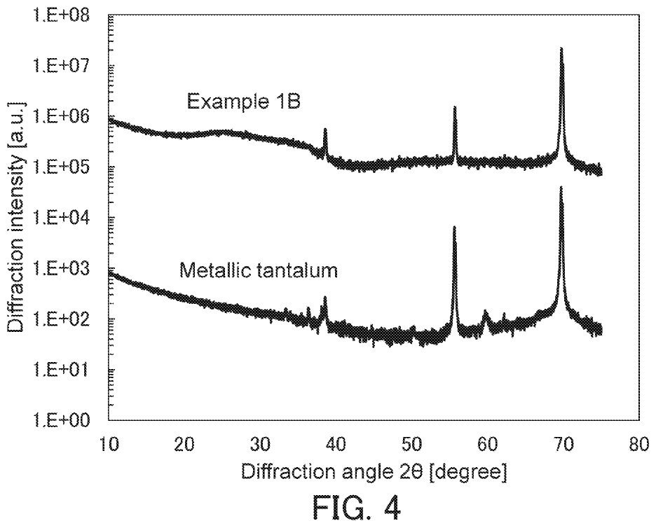

An XRD pattern of a specimen produced from the sample according to Example 1B was obtained by 2θ/θ scan using an X-ray diffractometer X'Pert PRO manufactured by Malvern Panalytical Ltd. Cu-Kα radiation was used as an X-ray source, the voltage was adjusted at 45 kV, and the current was adjusted at 40 mA. The wavelength of the Cu-Kα radiation was 0.15418 nm. FIG. 4 is a graph showing the results of the X-ray diffraction (XRD) measurement of the sample according to Example 1B and metallic tantalum. In FIG. 4, the vertical axis represents the diffraction intensity in arbitrary units, and the horizontal axis represents the diffraction angle 2θ. As shown in FIG. 4, although a diffraction peak derived from metallic tantalum is observed in the result of the XRD measurement of the sample according to Example 1B, a broad profile is observed over the entire pattern. This indicates that the tantalum oxide film of the sample according to Example 1B is amorphous. In the same manner, the tantalum oxide films of the samples according to the other Examples are suggested to be amorphous.

### (Elemental Composition Analysis)

Rutherford backscattering spectrometry (RBS) was performed on a specimen prepared from the dielectric film of the sample according to Comparative Example 2 using an RBS device Pelletron 5SDH-2. In the RBS, the specimen was irradiated with an ion beam under given conditions to give an RBS spectrum. According to the obtained RBS spectrum, the composition of a portion of the surface of the dielectric layer of the sample according to Comparative Example 2 was TaO_{2.27}F_{0.03}. In a portion of the dielectric film of the sample according to Comparative Example 2, a molar ratio of an amount of O to an amount of Ta was 2.48, and an amount of F was below the limit of detection, the portion being in contact with the metallic tantalum.

### (TOF-SIMS)

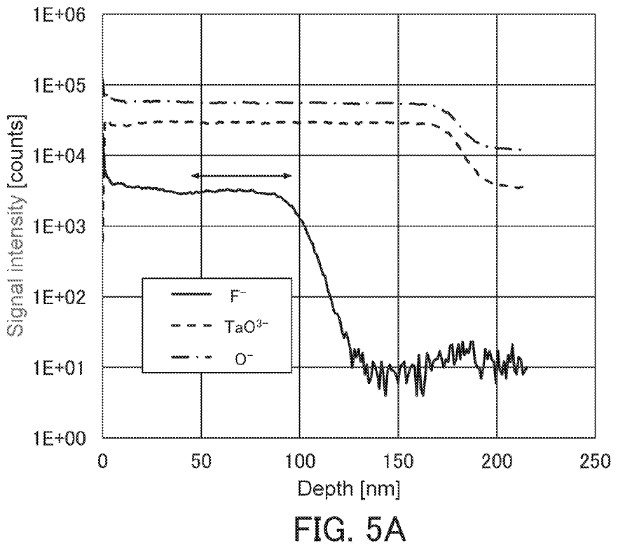

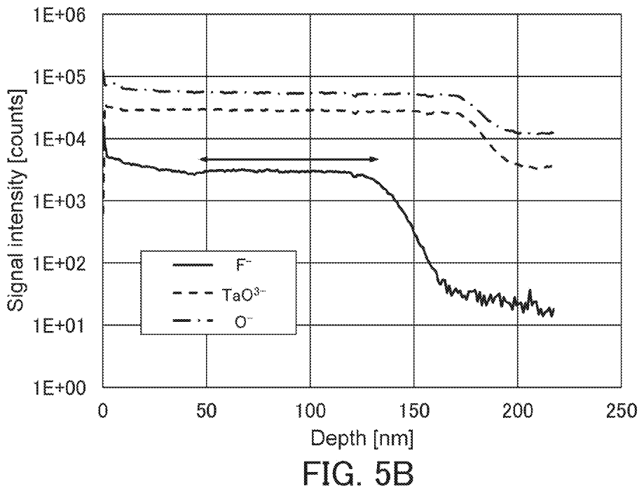

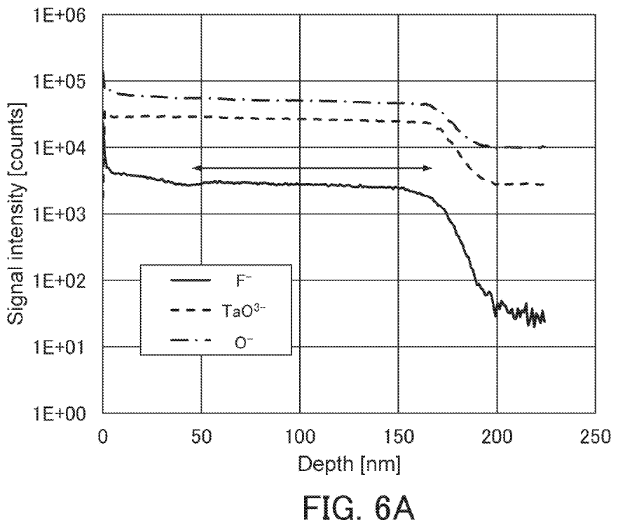

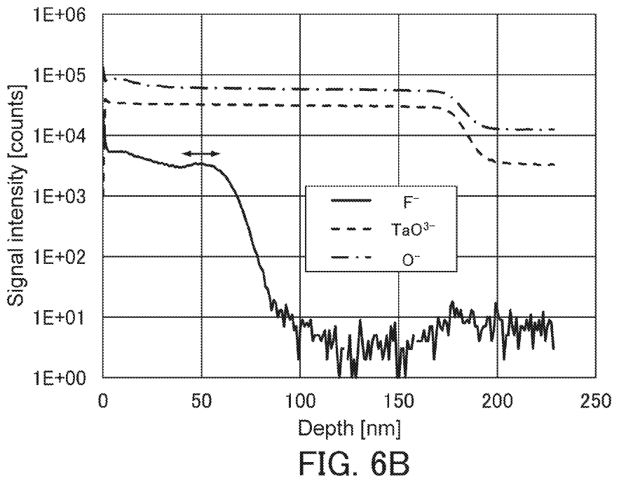

A piece having a given size was cut out of each of the samples according to Examples 1A and 1B and Comparative Examples 1 and 2, and a specimen for TOF-SIMS was prepared by resin embedding. Using a TOF-SIMS apparatus TOF.SIMS 5 manufactured by IONTOF GmbH, TOF-SIMS was performed on the specimen produced from each of the samples according to Examples 1A and 1B and Comparative Examples 1 and 2 to perform composition analysis in a depth direction of the tantalum oxide film. In the TOF-SIMS, a Bi ion beam was used as a primary ion beam. O₂⁺ was used as a sputtering ion species. FIG. 5A and FIG. 5B are graphs showing relationships between signal intensities of F⁻, TaO₃⁻, and O⁻ and the depth of the tantalum oxide film in depth profiles obtained from, respectively, the samples according to Examples 1A and 1B by TOF-SIMS. FIG. 6A and FIG. 6B are graphs showing relationships between signal intensities of F⁻, TaO₃⁻, and O⁻ and the depth of the tantalum oxide film in depth profiles obtained from, respectively, the samples according to Comparative Examples 1 and 2 by TOF-SIMS. In FIG. 5A, FIG. 5B, FIG. 6A, and FIG. 6B, the vertical axis represents the signal intensity of each ion, and the horizontal axis represents the depth of the dielectric film. In FIG. 5A, FIG. 5B, FIG. 6A, and FIG. 6B, a range used to calculate the maxima of the signal intensities of fluoride ion (F⁻) and tantalum oxide ion (TaO₃⁻) is indicated by a black bidirectional arrow.

From FIG. 5A, FIG. 5B, FIG. 6A, and FIG. 6B, it is understood that the tantalum oxide film of each of the samples according to Examples 1A and 1B and Comparative Examples 1 and 2 is provided on metallic tantalum and includes a first portion having a higher fluorine concentration and a second portion having a lower fluorine concentration. From FIG. 5A, FIG. 5B, FIG. 6A, and FIG. 6B, a range in which the signal intensity is equal to or greater than one half of the maximum of the signal intensity of fluoride ion (F⁻) in the first portion was identified, and the thickness d₁ of the first portion was calculated. This maximum is the maximum signal intensity in a range in which a fluoride ion (F⁻) signal can be accurately analyzed (the range indicated by the bidirectional arrow in each of FIG. 5A, FIG. 5B, FIG. 6A, and FIG. 6B). In this composition analysis, an influence of surface deposits or the like is observed in a depth range of 0 to approximately 40 nm. Therefore, this range was not used to identify the maximum of the signal intensity of fluoride ion (F⁻). Additionally, a range in which the signal intensity is equal to or greater than one half of the maximum of the signal intensity of tantalum oxide ion (TaO₃⁻) in the tantalum oxide film 30 was determined, and the thickness d₀ of the tantalum oxide film 30 was calculated. Thus, the ratio d₁/d₀ of the thickness d₁ of the first portion to the thickness d₀ of the tantalum oxide film was determined for the samples according to Examples 1A and 1B and Comparative Examples 1 and 2. Table 1 shows the results.

TABLE 1

| | Applied | | | |
|---|---|---|---|---|
| | voltage in | | | |
| | anodization | | | |
| | using aqueous | Thickness d₁ of | Thickness d₀ of | |
| | phosphoric | first | tantalum | |
| | acid solution | portion | oxide film | |
| | [V] | [nm] | [nm] | d₁/d₀ |
| Example 1A | 50 | 97.1 | 179.4 | 0.54 |
| Example 1B | 40 | 134.4 | 179.6 | 0.75 |
| Comparative | 30 | 168.1 | 174.3 | 0.96 |
| Example 1 | | | | |
| Comparative | 60 | 63.6 | 180.5 | 0.35 |
| Example 2 | | | | |

### Example 2A and Example 2B

In a state where one longitudinal end of an anode lead formed of a metallic tantalum stick was embedded in metallic tantalum powder, the tantalum powder was formed into a rectangular parallelepiped to give a formed body. This formed body was sintered to give an anode body that had a porous structure and where the one end of the anode lead was embedded.

Next, the anode body was immersed in an aqueous phosphoric acid solution, and a voltage of 40 V or 50 V was applied to the anode body for a given period of time using the anode lead to form a Ta₂O₅-including oxide layer on the surface of the anode body. The anode body was taken out of the aqueous phosphoric acid solution, washed with pure water, and then dried in air.

Next, the anode body with the oxide layer was partially immersed in an aqueous solution mixture of NaF and a sodium phosphate buffer, and a voltage of 90 V was applied to the anode body for a given period of time using the anode lead. A fluorine-containing tantalum oxide film was formed on the surface of the anode body in this manner. The anode body was taken out of the mixed solution, washed with pure water, and then dried for 10 minutes in a drying oven regulated at 100° C. Samples according to Example 2A and Example 2B were obtained in this manner. Conditions for forming the oxide layer and conditions for forming the fluorine-containing tantalum oxide film in Example 2A and Example 2B were adjusted to be the same as those in Example 1A and Example 1B, respectively. Therefore, it was assumed that the ratios d₁/d₀ of the thickness d₁ of the first portion to the thickness d₀ of the tantalum oxide film for the samples according to Example 2A and Example 2B were the same as the ratios d₁/d₀ for the samples according to Example 1A and Example 1B, respectively.

### Comparative Example 3

A sample according to Comparative Example 3 was obtained in the same manner as in Example 2A and Example 2B, except that the voltage applied to the anode body was changed to 30 V in the oxide layer formation using the aqueous phosphoric acid solution.

Conditions for forming the oxide layer and conditions for forming the fluorine-containing tantalum oxide film in Comparative Example 3 were adjusted to be the same as those in Comparative Example 1. Therefore, it was assumed that the ratio d₁/d₀ of the thickness d₁ of the first portion to the thickness d₀ of the tantalum oxide film for the samples according to Comparative Example 3 was the same as the ratio d₁/d₀ for the samples according to Comparative Example 1.

### Comparative Example 4

A sample according to Comparative Example 4 was obtained in the same manner as in Example 2A and Example 2B, except that the voltage applied to the anode body was changed to 60 V in the oxide layer formation using the aqueous phosphoric acid solution. Conditions for forming the oxide layer and conditions for forming the fluorine-containing tantalum oxide film in Comparative Example 4 were adjusted to be the same as those in Comparative Example 2. Therefore, it was assumed that the ratio d₁/d₀ of the thickness d₁ of the first portion to the thickness d₀ of the tantalum oxide film for the samples according to Comparative Example 4 was the same as the ratio d₁/d₀ for the samples according to Comparative Example 2.

### Comparative Example 5

An anode body prepared in the same manner as in Example 2A and Example 2B was immersed in an aqueous phosphoric acid solution, and a voltage of 80 V was applied to the anode body for a given period of time using the anode lead to form a Ta₂O₅-including oxide layer on the surface of the anode body. The anode body was taken out of the aqueous phosphoric acid solution, washed with pure water, and then dried for 10 minutes in a drying oven regulated at 100° C. A sample according to Comparative Example 5 was obtained in this manner. Since no fluorine-containing tantalum oxide film was formed in Comparative Example 5, the ratio d₁/d₀ is 0 for Comparative Example 5.

### (Capacitance and Dielectric Loss Tangent)

Dielectric properties of the samples according to Example 2A, Example 2B, Comparative Example 3, Comparative Example 4, and Comparative Example 5 were evaluated by an AC impedance method. In the evaluation, the amplitude was adjusted to 500 mV. Additionally, while varying the frequency in the range of 200 Hz to 80 Hz, capacitances were calculated from resistance values at five different frequencies in this range, and a capacitance at 120 Hz was calculated from an approximate straight line obtained from the data of the five points. A dielectric loss tangent tan δ at 120 Hz was calculated in the same manner.

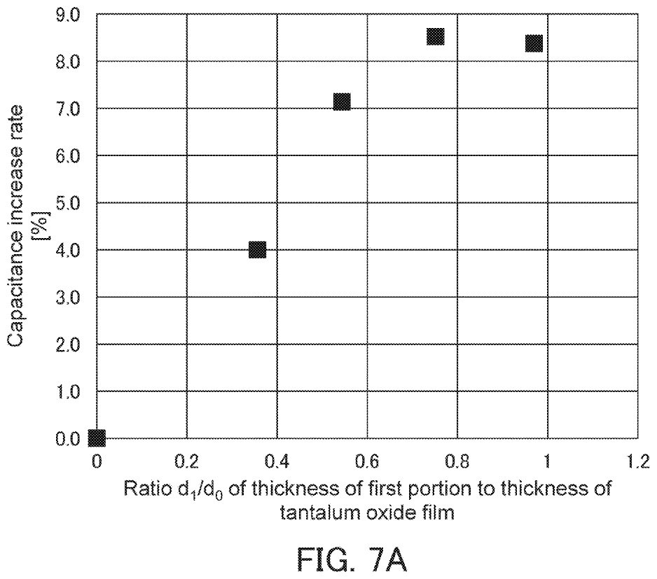

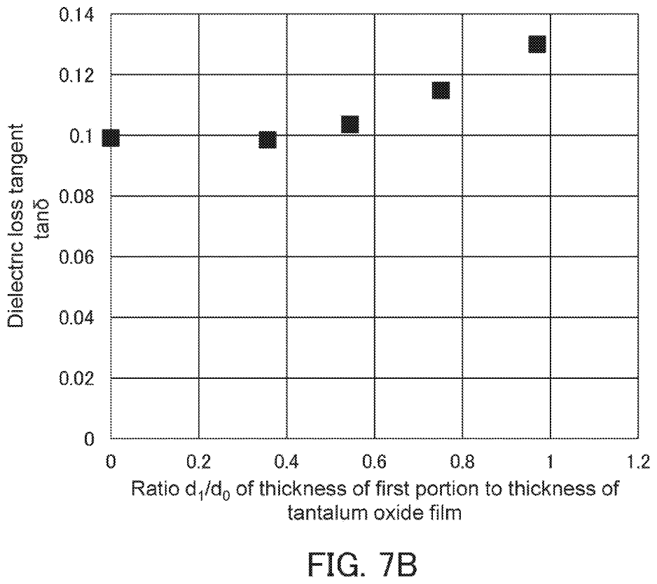

FIG. 7A is a graph showing a relationship between a capacitance increase rate and the ratio of the thickness of the first portion to the thickness of the tantalum oxide film for the samples according to Example 2A, Example 2B, Comparative Example 3, Comparative Example 4, and Comparative Example 5. FIG. 7B is a graph showing a relationship between the dielectric loss tangent tan δ of the tantalum oxide film and the ratio of the thickness of the first portion to the thickness of the tantalum oxide film for the samples according to Example 2A, Example 2B, Comparative Example 3, Comparative Example 4, and Comparative Example 5. In FIG. 7A and FIG. 7B, the plot where the ratio d₁/d₀ is 0 corresponds to Comparative Example 5. The capacitance increase rate is expressed as a percentage of a ratio of a difference obtained by subtracting the capacitance of the sample according to Comparative Example 5 from the capacitance of each of the samples according to Example 2A, Example 2B, Comparative Example 3, and Comparative Example 4 to the capacitance of the sample according to Comparative Example 5.

The tantalum oxide films of the samples according to Example 2A, Example 2B, Comparative Example 3, Comparative Example 4, and Comparative Example 5 are on metallic tantalum having similar surface conditions, and it is thought that the tantalum oxide films of the samples have about the same surface area. According to FIG. 7A and FIG. 7B, as the ratio of the thickness of the first portion to the thickness of the tantalum oxide film decreases, the dielectric loss tangent tan δ of the tantalum oxide film decreases, but the capacitance increase rate also decreases. When the ratio d₁/d₀ is more than 0.4 and 0.8 or less, the dielectric loss tangent tan δ of the tantalum oxide film is not very high, compared to the dielectric loss tangent tan δ of the tantalum oxide film of the sample according to Comparative Example 5. Moreover, it can be said that when the ratio d₁/d₀ is more than 0.4 and 0.8 or less, the capacitance is effectively increased, compared to the capacitance of the sample according to Comparative Example 5.

### INDUSTRIAL APPLICABILITY

The capacitor according to the present disclosure is advantageous in terms of the capacitance of the capacitor and the dielectric loss tangent of the tantalum oxide film.

What is claimed is:

1. A capacitor comprising:
metallic tantalum;
an electrical conductor; and
a tantalum oxide film disposed in contact with the metallic tantalum and between the metallic tantalum and the electrical conductor, wherein
the tantalum oxide film includes a first portion containing fluorine and a second portion located closer to the metallic tantalum than the first portion in a thickness direction of the tantalum oxide film,
a fluorine concentration in the second portion is lower than a fluorine concentration in the first portion, and
a ratio of a thickness of the first portion to a thickness of the tantalum oxide film is more than 0.4 and 0.8 or less.

2. The capacitor according to claim 1, wherein the first portion is amorphous.

3. The capacitor according to claim 1, wherein
the first portion has a composition represented by TaOₓ₁F_{y1}, and
the composition satisfies requirements 0<x1<2.5 and 0<y1≤0.4.

4. The capacitor according to claim 1, wherein
the second portion has a composition represented by TaOₓ₂F_{y2}, and
the composition satisfies requirements 0<x2<2.5 and 0<y2≤0.015.

5. The capacitor according to claim 1, further comprising an electrolyte disposed between the tantalum oxide film and the electrical conductor in the thickness direction of the tantalum oxide film.

6. An electrical circuit comprising the capacitor according to claim 1.

7. A circuit board comprising the capacitor according to claim 1.

8. An apparatus comprising the capacitor according to claim 1.
